(19) United States
(12) Patent Application Publication
(10) Pub. No.: US 2015/0364582 A1
(43) Pub. Date: Dec. 17, 2015

(54) SEMICONDUCTOR DEVICE

(71) Applicant: KABUSHIKI KAISHA TOSHIBA, Tokyo (JP)

(72) Inventor: Masakazu GOTO, Yokohama (JP)

(73) Assignee: KABUSHIKI KAISHA TOSHIBA, Minato-Ku, Tokyo (JP)

(21) Appl. No.: 14/560,943

(22) Filed: Dec. 4, 2014

(30) Foreign Application Priority Data
Jun. 16, 2014 (JP) 2014-123714

(51) Int. Cl. H01L 29/66; H01L 29/10; H01L 29/78; H01L 29/08; H01L 29/165; H01L 29/267

(52) U.S. Cl. CPC H01L 29/66977; H01L 29/165; H01L 29/267; H01L 29/7848; H01L 29/0847; H01L 29/1054

(57) ABSTRACT

A semiconductor device includes a gate dielectric film on a semiconductor layer. A gate electrode is above the semiconductor layer via the gate dielectric film. A first conductivity-type drain is in the semiconductor layer on one end side of the gate electrode. A second conductivity-type source is in the semiconductor layer on the other end side of the gate electrode and below the gate electrode. A channel is between the gate dielectric film and the source. A drain side end of the source is below a bottom surface of the gate electrode. A region of the drain side end of a surface region of the source is formed using a first material. A region of the surface region of the source other than the drain side end is formed using a second material. An energy band gap of the first material is larger than that of the second material.

### CROSS REFERENCE TO RELATED APPLICATIONS

This application is based upon and claims the benefit of priority from the prior Japanese Patent Application No. 2014-123714, filed on Jun. 16, 2014, the entire contents of which are incorporated herein by reference.

### FIELD

The embodiments of the present invention relate to a semiconductor device.

### BACKGROUND

In recent years, TFETs (Tunnel Field-Effect Transistors) that employ the quantum-mechanical effects of electrons have been developed. When TFETs become an on-state, a voltage is applied to a gate electrode, so that BTBT (Band To Band Tunneling) occurs between a source and a channel.

In such TFETs, a vertical TFET in which a source and a channel region are provided below a gate electrode and BTBT occurs in a direction of applying a gate electric field has been proposed. According to such a vertical TFET, when a drain side end of a source is extended further in a drain direction than a drain side end of a gate electrode (when a gate electrode does not cover a part above a drain side end of a source), the drain side end of the source is not controlled by a gate voltage and thus a parasitic tunneling current is suppressed at a source end. However, a depletion layer is extended from the drain side end of the source, and thus this depletion layer becomes a potential barrier and an on-current Ion is degraded.

On the other hand, when the drain side end of the gate electrode is extended further in the drain direction than the drain side end of the source (when the gate electrode covers the part above the drain side end of the source), the drain side end of the source is controlled by the gate voltage and thus the depletion layer is not extended too much from the source end. For this reason, a high on-current Ion can be obtained. However, a parasitic tunneling current is generated at the drain side end of the source, and thus sub-threshold characteristics (hereinafter, also “SS characteristics”) are degraded.

As explained above, the vertical TFET has a trade-off relationship between the SS characteristics and the on-current Ion depending on the relative positional relationship between a source end and a gate electrode end.

### BRIEF DESCRIPTION OF THE DRAWINGS

FIG. 1 is a cross-sectional view showing an example of a configuration of a tunneling semiconductor device 100 according to a first embodiment;

FIG. 2 is an energy band diagram of an N-TFET;

FIGS. 3A to 7B are cross-sectional views showing an example of the manufacturing method of the N-TFET 100 according to the first embodiment;

FIG. 8 is a cross-sectional view showing an example of a configuration of a P-TFET 200 according to a second embodiment;

FIG. 9 is an energy band diagram of a P-TFET;

FIGS. 10A to 13 are cross-sectional views showing an example of the manufacturing method of the P-TFET 200 according to the second embodiment; and

FIG. 14 is a cross-sectional view showing a configuration of a complementary TFET 300 according to a third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the present embodiment includes a semiconductor layer. A gate dielectric film is provided on the semiconductor layer. A gate electrode is provided above the semiconductor layer via the gate dielectric film. A first conductivity type drain layer is provided in the semiconductor layer on one end side of the gate electrode. A second conductivity type source layer is provided in the semiconductor layer on the other end side of the gate electrode and below the gate electrode. A channel layer is provided between the gate dielectric film and the source layer. A drain side end of the source layer is below a bottom surface of the gate electrode. A region of the drain side end of a surface region of the source layer is formed using a first material. A region of the surface region of the source layer other than the drain side end is formed using a second material. An energy band gap of the first material is larger than that of the second material.

### FIRST EMBODIMENT

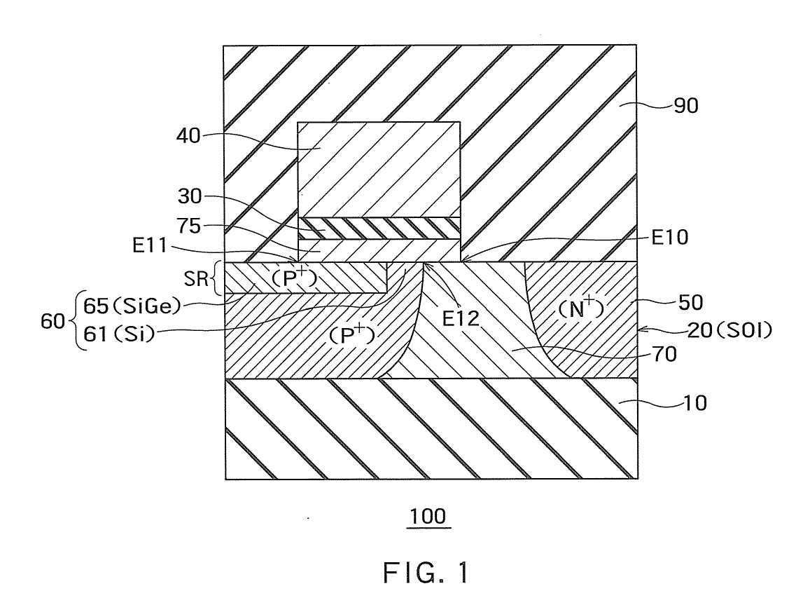

FIG. 1 is a cross-sectional view showing an example of a configuration of a tunneling semiconductor device (hereinafter, also “TFET”) 100 according to a first embodiment. The TFET 100 includes a BOX (Buried Oxide) layer 10, a semiconductor layer 20, a gate dielectric film 30, a gate electrode 40, a drain layer 50, a source layer 60, a channel layer 75, a low concentration layer 70, and an interlayer dielectric film 90.

The semiconductor layer 20 is a SOI (Silicon On Insulator) layer provided on the BOX layer 10.

The gate dielectric film 30 is provided on the semiconductor layer 20. For example, the gate dielectric film 30 is formed of a silicon oxide film or a dielectric material with higher dielectric constant than the silicon oxide film.

The gate electrode 40 is provided above the semiconductor layer 20 with the gate dielectric film 30 interposed therebetween. The gate electrode 40 is also provided on the source layer 60 and the low concentration layer 70. For example, the gate electrode 40 is formed of a conductive material such as N-type doped polysilicon.

The N⁺-type drain layer 50 is provided within the semiconductor layer 20 on a side of one end E10 of the gate electrode 40. The drain layer 50 is not provided immediately under the gate electrode 40 and is spaced away from the gate electrode 40. That is, the drain layer 50 is provided at a position that is offset from the gate electrode 40. Therefore, a bottom surface of the gate electrode 40 does not face the drain layer 50.

The P⁺-type source layer 60 is provided within the semiconductor layer 20 on a side of the other end E11 of the gate electrode 40 and below the gate electrode 40. A drain-side end E12 (hereinafter, also “source end E12”) of the source layer 60 is below the bottom surface of the gate electrode 40. That is, the gate electrode 40 is placed above the source end E12 and is extended further to a drain side than the source end E12. In other words, the gate electrode 40 covers a part above the source end E12 with the gate dielectric film 30 interposed therebetween. As a result, an electric field from the gate electrode 40 acts upon the source end E12 and a depletion layer is prevented from being extended from the source end E12.

A surface region SR of the source layer 60 includes a first region 61 and a second region 65. The first region 61 is a region of the surface region SR of the source layer 60 that includes the source end E12. The second region 65 is a region of the surface region SR of the source layer 60 other than the first region 61.

The first region 61 is formed using a first material with a relatively wide energy band gap (hereinafter, also “wide-Eg material”), and the second region 65 is formed using a second material with a relatively narrow energy band gap (hereinafter, also “narrow-Eg material”). The first region 61 is thus formed using a material with a wider energy band gap than the second region 65. In other words, the first region 61 is formed using a material with a lower tunneling probability than the second region 65. For example, the wide-Eg material as the first material is silicon. For example, the narrow-Eg material as the second material is formed of at least one of SiGe, Ge, and InGaAs. In the first embodiment, SiGe is used as the narrow-Eg material.

The channel layer 75 is provided on the source layer 60, and faces the bottom surface of the gate electrode 40 with the gate dielectric film 30 interposed therebetween. That is, the channel layer 75 is provided between the gate dielectric film 30 and the source layer 60. For example, the channel layer 75 is a semiconductor layer having an impurity concentration of 10¹⁶/cm³ or less (so-called “intrinsic semiconductor layer”).

Explanations are given below assuming that the channel layer 75 is a part of the semiconductor layer 20. Alternatively, while the channel layer 75 can be a layer formed by implanting a P-type impurity (for example, boron) in the semiconductor layer 20, the impurity concentration of this layer is lower than that of the source layer 60 or the drain layer 50.

The low concentration layer 70 is provided within the semiconductor layer 20 between the drain layer 50 and the source layer 60. The low concentration layer 70 separates the drain layer 50 from the source layer 60. The low concentration layer 70 is a semiconductor layer having a lower impurity concentration than the drain layer 50 and the source layer 60. For example, the low concentration layer 70 can be a semiconductor layer having an impurity concentration of 10¹⁶/cm³ or less (so-called “intrinsic semiconductor layer”).

The interlayer dielectric film 90 covers the gate electrode 40, the drain layer 50, the source layer 60, and the like. For example, the interlayer dielectric film 90 is formed of a TEOS film or an insulation film such as a silicon oxide film. A wiring structure (not shown) constituted by contacts, metal wires, interlayer dielectric films, and the like is provided within or on the interlayer dielectric film 90.

To cause the N-TFET 100 according to the first embodiment to become an on-state, voltages with the same sign are applied to the gate electrode 40 and the drain layer 50, respectively. For example, it is assumed that when the TFET 100 is in an off-state, 0 V is applied to the source layer 60 and a positive voltage (for example, 1 V) is applied to the drain layer 50. That is, it is assumed that a reverse bias is applied to a junction between the low concentration layer 70 and the drain layer 50.

To cause the TFET 100 to become an on-state, a positive voltage is applied to the gate electrode 40. However, in a case where a gate voltage is less than a threshold voltage of the TFET 100 when a source voltage (for example, 0 V) is used as a reference, the TFET 100 is in an off-state. At this time, tunneling of electrons from the source layer 60 is prohibited. That is, only a considerably small current (an off-leak current) caused by a reverse bias flows between the source layer 60 and the drain layer 50, and thus it is conceivable that the TFET 100 is in an off-state.

Meanwhile, when a positive voltage with respect to the source voltage is applied to the gate electrode 40, depletion of the channel region 75 controlled by an electric field from the gate electrode 40 starts. When the gate voltage is equal to or larger than a threshold voltage with respect to the source voltage, band-to-band tunneling (BTBT) of electrons occurs between the source layer 60 and the channel layer 75. A voltage of the gate electrode 40 when BTBT occurs is called a threshold voltage of the TFET 100. The threshold voltage is a gate voltage indicating that the TFET 100 is in an on-state.

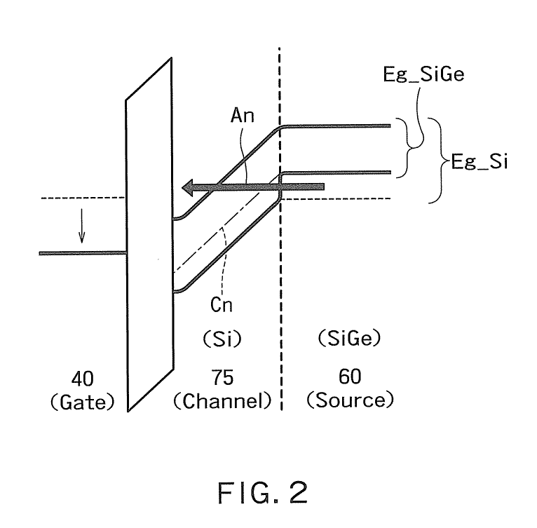

The threshold voltage of the TFET 100 and the on-current Ion depend on a material for a tunnel junction between the channel layer 75 and the source layer 60. For example, as an energy band gap becomes narrow (the tunneling probability becomes high), BTBT occurs at a low gate voltage. For this reason, if a material with a narrow energy band gap is used for the tunnel junction, the threshold voltage of the TFET 100 is reduced and the on-current Ion is increased. However, when taking a direction in which BTBT occurs (a direction in which electrons flow) into consideration, a position where a material with a narrow energy band gap should be applied is different between an N-TFET and a P-TFET. For example, FIG. 2 is an energy band diagram of an N-TFET. The N-TFET of FIG. 2 uses a narrow-Eg material SiGe for the source layer 60 and a wide-Eg material Si for the channel layer 75. Eg_SiGe denotes an energy band gap of SiGe and Eg_Si denotes an energy band gap of Si.

When the N-TFET becomes an on-state, BTBT occurs from the source layer 60 toward the channel layer 75 as indicated by the arrow An in FIG. 2. Therefore, by using SiGe with a narrower energy band gap (with a higher tunneling probability) than silicon for the source layer 60, BTBT becomes easy to occur from a valence band of the source layer 60 toward a conduction band of the channel layer 75. That is, the threshold voltage of the N-TFET is reduced and the on-current Ion is increased.

According to the first embodiment, the narrow-Eg material SiGe with a relatively narrow energy band gap (with a high tunneling probability) is used for the second region 65 of the surface region SR of the source layer 60. BTBT thus becomes easy to occur between the second region 65 and the channel layer 75, so that the threshold voltage is reduced and the on-current Ion is increased.

Meanwhile, an electric field from the gate electrode 40 is easy to concentrate on the source end E12. Accordingly, when the narrow-Eg material SiGe is also used for the first region 61, BTBT at the source end E12 occurs at a lower gate voltage as compared to BTBT in the second region 65. That is, when a gate voltage is increased, parasitic BTBT locally occurs (a parasitic tunneling current is locally generated) at the source end E12 and then BTBT occurs in the second region 65. In this case, a drain current is gradually increased along with the increase in the gate voltage and thus SS characteristics are degraded.

In the first embodiment, the wide-Eg material Si with a relatively wide energy band gap (with a low tunneling probability) is used for the first region 61 of the surface region SR of the source layer 60, including the source end E12. A threshold voltage in the first region 61 is thus higher than that in the second region 65, and occurrence of parasitic BTBT at the source end E12 is suppressed. As a result, degradation of the SS characteristics is also suppressed.

Further, the gate electrode 40 covers the part above the source end E12. Therefore, an electric field from the gate electrode 40 is applied to the source end E12, and thus a depletion layer is difficult to be extended at the source end E12, and the on-current Ion between the source layer 60 and the channel layer 75 can flow into the drain layer 50 without being blocked at the source end E12.

As explained above, the TFET 100 according to the first embodiment uses the wide-Eg material Si for the first region 61 of the surface region SR of the source layer 60 and uses the narrow-Eg material SiGe for the second region 65. Further, the gate electrode 40 covers the part above the source end E12. Therefore, the N-TFET 100 can obtain steep SS characteristics and a large on-current Ion, and can break the trade-off relationship between the SS characteristics and the on-current Ion.

Next, a manufacturing method of the N-TFET 100 according to the first embodiment is explained.

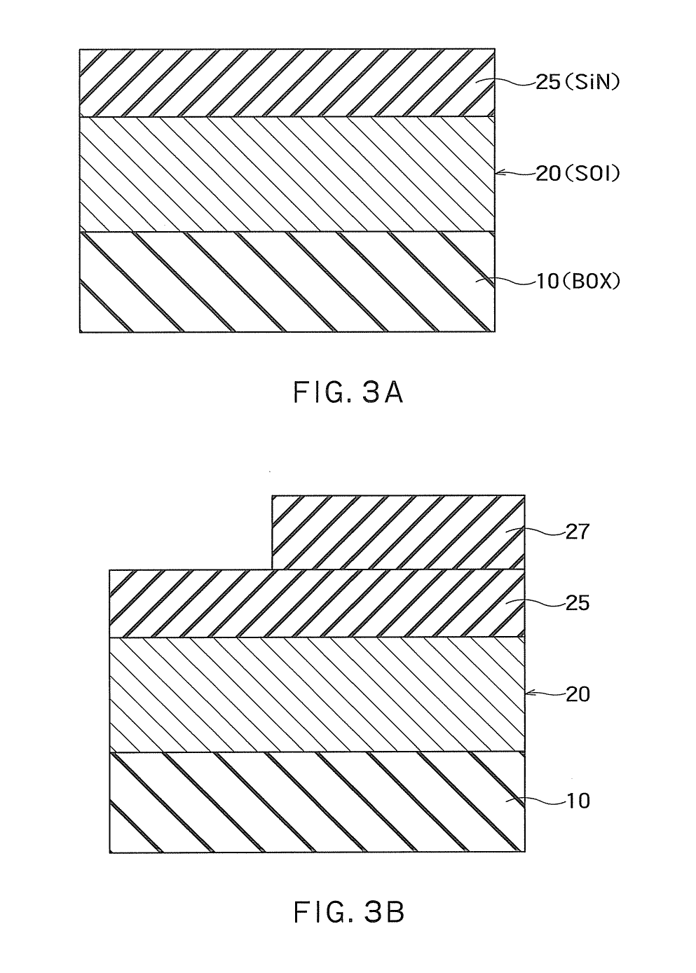

FIGS. 3A to 7B are cross-sectional views showing an example of the manufacturing method of the N-TFET 100 according to the first embodiment.

As shown in FIG. 3A, a material for the hard mask 25 is formed first on the semiconductor layer 20. For example, the material for the hard mask 25 is an insulation film such as SiN. The semiconductor layer 20 can be a SOI layer (Si) of a SOI substrate or can be a silicon layer formed by using a bulk silicon substrate. Alternatively, the semiconductor layer 20 can be a silicon layer that is epitaxially grown on an arbitrary substrate. When a SOI substrate is used, reference numeral 10 denotes a BOX layer.

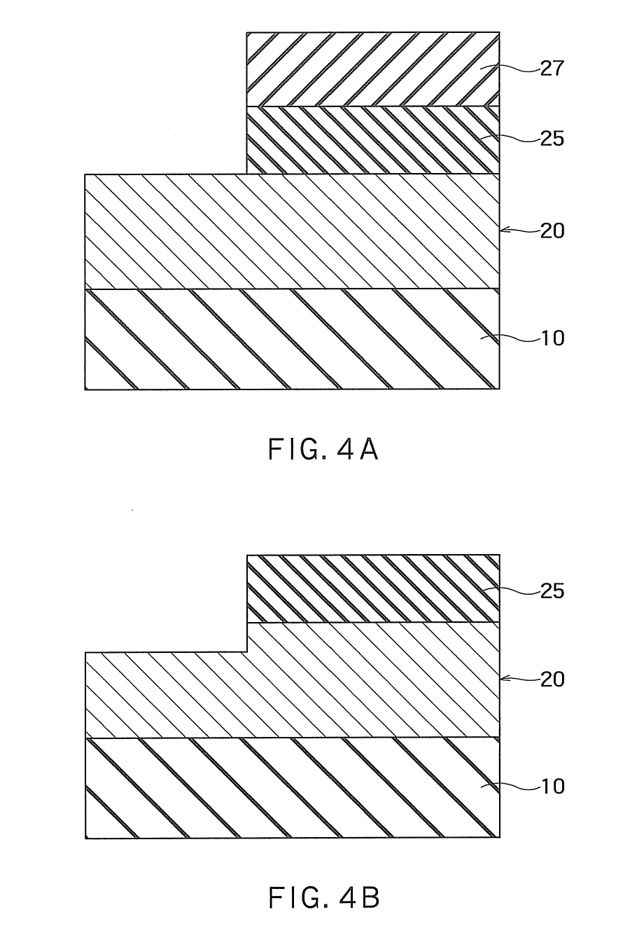

Next, as shown in FIG. 3B, a photoresist 27 is formed on the hard mask 25 by a lithography technique. The photoresist 27 covers a region other than a region where the second region 65 of the source layer 60 is formed later. Next, as shown in FIG. 4A, the hard mask 25 is etched by RIE (Reactive Ion Etching) by using the photoresist 27 as a mask.

After the photoresist 27 is removed, as shown in FIG. 4B, an upper part of the semiconductor layer 20 is etched by RIE by using the hard mask 25 as a mask.

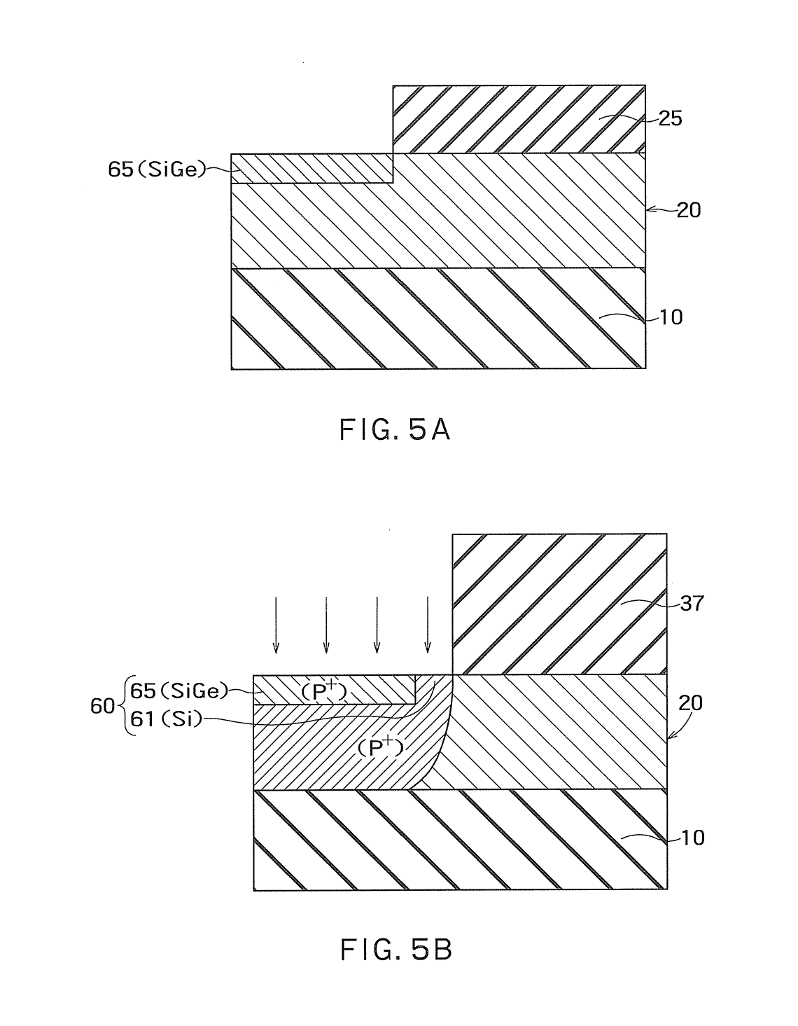

Next, as shown in FIG. 5A, the narrow-Eg material SiGe is grown in an etched region of the semiconductor layer 20 by epitaxial CVD. For example, a narrow-Eg material can be, in addition to SiGe, Ge or InGaAs. The narrow-Eg material SiGe is thus formed in the second region 65.

After the hard mask 25 is removed by wet etching using a hot phosphoric acid and the like, a region other than a region where the source layer 60 is formed is covered by the photoresist 37.

Next, as shown in FIG. 5B, a P-type impurity (for example, B or BF₂) is implanted in the region where the source layer 60 is formed by using the photoresist 37 as a mask. At this time, a region subjected to ion implantation is extended further to a drain side than the second region 65 having the narrow-Eg material SiGe formed therein. The P-type impurity is thus implanted in the second region 65 formed using the narrow-Eg material SiGe and the first region 61 formed using the wide-Eg material Si at a high concentration.

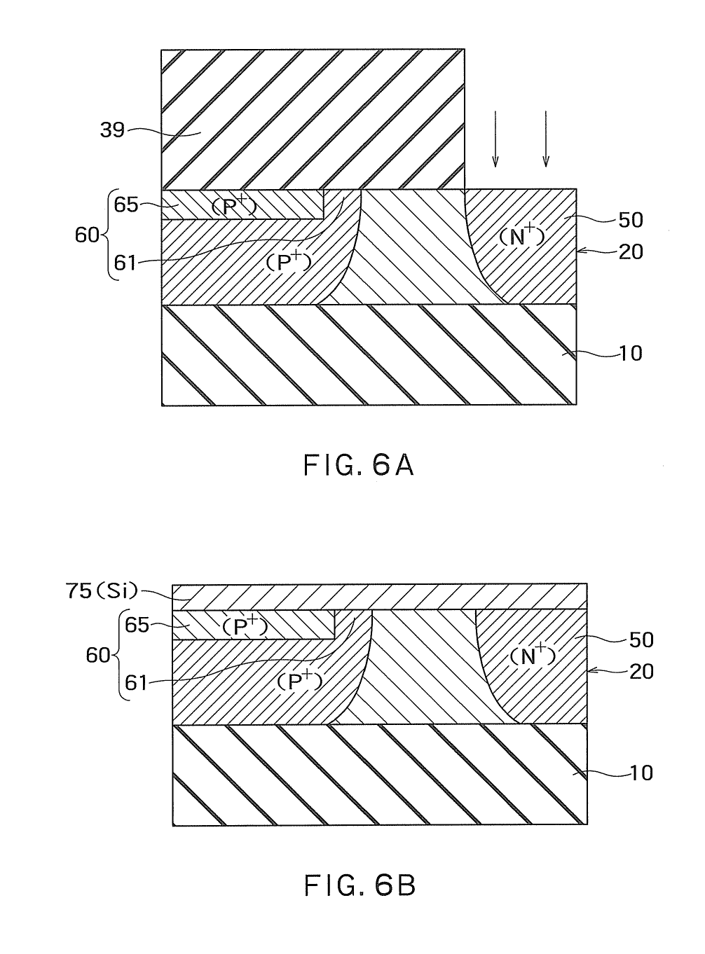

After the photoresist 37 is removed, as shown in FIG. 6A, a region other than a region where the drain layer 50 is formed is covered by a photoresist 39 by a lithography technique. Next, an N-type impurity (for example, As or P) is implanted in the region where the drain layer 50 is formed by using the photoresist 39 as a mask.

After the photoresist 39 is removed, activation annealing of an impurity is performed by RTA (Rapid Thermal Anneal) and the like. In this manner, the drain layer 50 and the source layer 60 are formed.

Next, as shown in FIG. 6B, the channel layer 75 is grown on the semiconductor layer 20 by epitaxial CVD (Chemical Vapor Deposition). The channel layer 75 is formed of, for example, Si, SiGe, Ge, or InGaAs, and constitutes a part of the semiconductor layer 20.

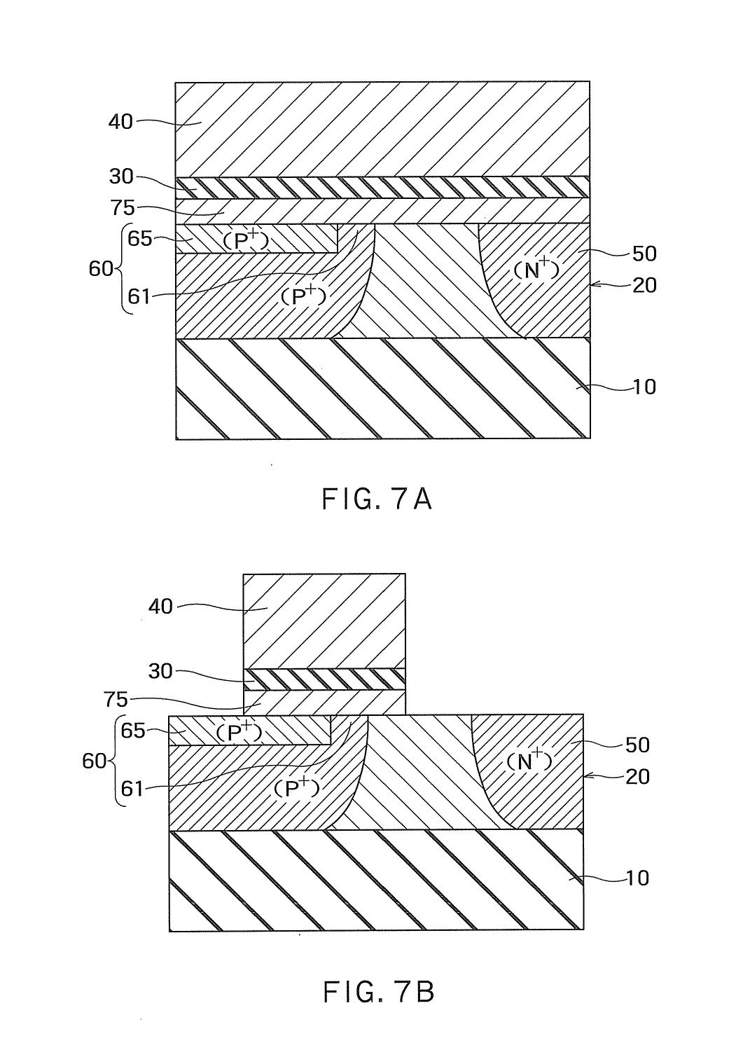

Next, as shown in FIG. 7A, by thermally oxidizing the channel layer 75 (the semiconductor layer 20), the gate dielectric film 30 is formed on the channel layer 75. The gate dielectric film 30 can also be formed by depositing a material for the gate dielectric film 30 on the channel layer 75. A material for the gate electrode 40 is further deposited on the gate dielectric film 30. The material for the gate electrode 40 is, for example, doped polysilicon.

Next, as shown in FIG. 7B, the gate electrode 40, the gate dielectric film 30, and the channel layer 75 are processed by a lithography technique and RIE. At this time, the gate electrode 40 is processed so that a bottom surface of the gate electrode 40 covers the part above the source end E12. As a result, a configuration shown in FIG. 7B is obtained.

Thereafter, the interlayer dielectric film 90, contacts (not shown), metal wires (not shown), and the like are formed, so that the N-TFET 100 shown in FIG. 1 is completed.

According to the first embodiment, the wide-Eg material Si is used for the first region 61 of the source layer 60, and the narrow-Eg material SiGe is used for the second region 65 of the source layer 60. Therefore, parasitic BTBT is prevented from occurring at the source end E12, and BTBT becomes easy to occur between the second region 65 and the channel layer 75. Degradation of the SS characteristics is thus suppressed, and a threshold voltage is reduced and the on-current Ion is increased. Further, the gate electrode 40 covers the part above the source end E12. Therefore, an electric field from the gate electrode 40 is applied to the source end E12, and thus the on-current Ion can flow into the drain layer 50 without being blocked by a depletion layer at the source end E12. As a result, the N-TFET 100 according to the first embodiment can break the trade-off relationship between the SS characteristics and the on-current Ion.

### SECOND EMBODIMENT

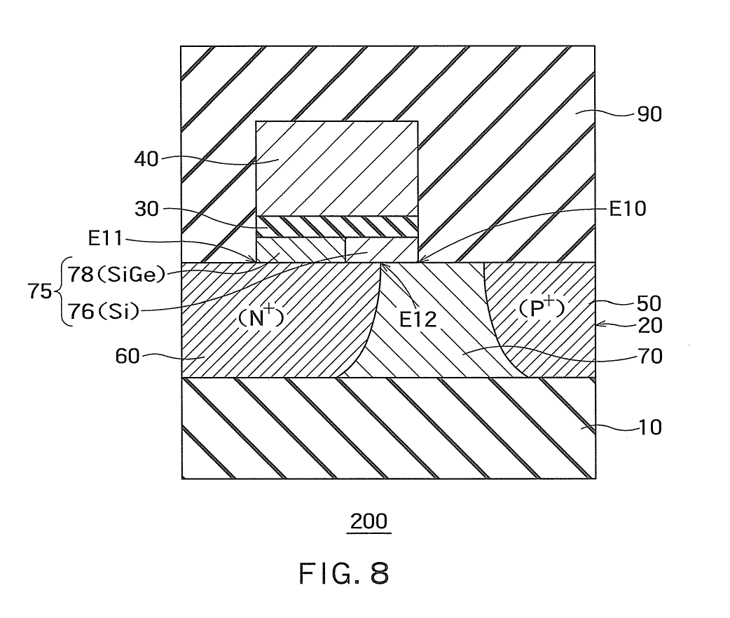

FIG. 8 is a cross-sectional view showing an example of a configuration of a P-TFET 200 according to a second embodiment. In the P-TFET 200, the channel layer 75 includes a third region 76 that contacts the source end E12 and a fourth region 78 that contacts a region other than the source end E12. The third region 76 is formed using a wide-Eg material serving as a first material, and the fourth region 78 is formed using a narrow-Eg material serving as a second material. As explained above, for example, the wide-Eg material is Si. For example, the narrow-Eg material is formed of at least one of SiGe, Ge, and InGaAs. Also in the second embodiment, SiGe is used as the narrow-Eg material.

The channel layer 75 is provided on the source layer 60, and faces a bottom surface of the gate electrode 40 with the gate dielectric film 30 interposed therebetween. The channel layer 75 is, for example, a semiconductor layer having an impurity concentration of 10¹⁶/cm³ or less (so-called “intrinsic semiconductor layer”). Alternatively, while the channel layer 75 can be a layer formed by implanting an N-type impurity (for example, phosphor or arsenic) in the semiconductor layer 20, the impurity concentration of the channel layer 75 is lower than that of the source layer 60 or the drain layer 50.

Meanwhile, a surface region of the source layer 60 is formed using one kind of a material (for example, Si). Because the TFET 200 is a P-TFET, the conductivity type of the source layer 60 is N⁺ and the conductivity type of the drain layer 50 is P⁺. Other configurations of the P-TFET 200 can be identical to corresponding ones of the N-TFET 100 according to the first embodiment.

To cause the P-TFET 200 to become an on-state, a negative voltage is applied to the gate electrode 40 and the drain layer 50. That is, a voltage of the opposite sign (a negative voltage) to a voltage (a positive voltage) that is applied to the gate electrode 40 and the drain layer 50 of the N-TFET 100 is applied to the gate electrode 40 and the drain layer 50 of the P-TFET 200. Therefore, when an absolute value of a gate voltage is equal to or larger than an absolute value of a threshold voltage with respect to a source voltage, band-to-band tunneling (BTBT) of electrons occurs between the source layer 60 and the channel layer 75.

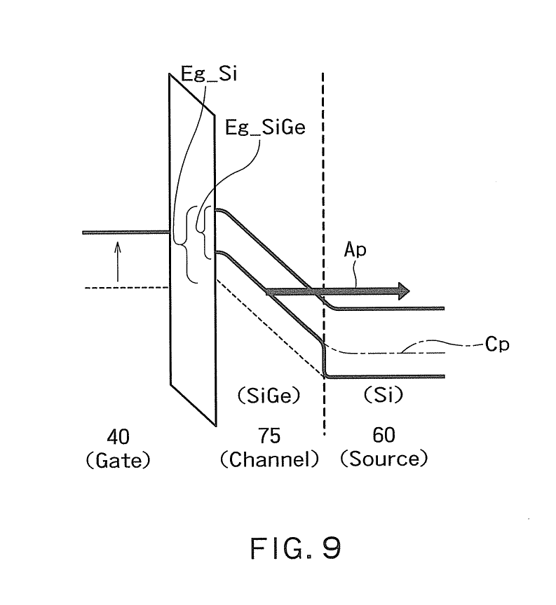

As explained above, a threshold voltage of the TFET 200 and the on-current Ion depend on a material for a tunnel junction between the channel layer 75 and the source layer 60. If a material with a narrow energy band gap is used for the tunnel junction, the threshold voltage of the TFET 200 is reduced and the on-current Ion is increased. However, when taking a direction in which BTBT occurs (a direction in which electrons flow) into consideration, a position where a material with a narrow energy band gap should be applied is different between an N-TFET and a P-TFET. For example, FIG. 9 is an energy band diagram of a P-TFET. The P-TFET of FIG. 9 uses the narrow-Eg material SiGe for the channel layer 75 and the wide-Eg material Si for the source layer 60. Eg_SiGe denotes an energy band gap of SiGe and Eg_Si denotes an energy band gap of Si.

When the P-TFET becomes an on-state, BTBT occurs from the channel layer 75 toward the source layer 60 as indicated by the arrow Ap in FIG. 9. Therefore, by using SiGe with a narrower energy band gap (with a higher tunneling probability) than silicon for the channel layer 75, BTBT becomes easy to occur from a valence band of the channel layer 75 toward a conduction band of the source layer 60. That is, a threshold voltage of the P-TFET is reduced and the on-current Ion is increased.

According to the second embodiment, the narrow-Eg material SiGe with a relatively narrow energy band gap (with a high tunneling probability) is used for the fourth region 78 of the channel layer 75 contacting the source layer 60. BTBT thus becomes easy to occur between the source layer 60 and the fourth region 78, so that the threshold voltage is reduced and the on-current Ion is increased.

Meanwhile, an electric field from the gate electrode 40 is easy to concentrate on the source end E12. Accordingly, when the narrow-Eg material SiGe is also used for the third region 76 of the channel layer 75, BTBT in the third region 76 placed on the source end E12 occurs by application of a smaller gate voltage as compared to BTBT in the fourth region 78. That is, when an absolute value of a gate voltage is increased, parasitic BTBT locally occurs (a parasitic tunneling current is locally generated) in the third region 76 of the channel layer 75 and then BTBT occurs in the fourth region 78. In this case, a drain current is gradually increased along with the increase in the absolute value of the gate voltage and thus SS characteristics are degraded.

Therefore, in the second embodiment, the wide-Eg material Si with a relatively wide energy band gap (with a low tunneling probability) is used for the third region 76 of the channel layer 75 on a drain side (contacting the source end E12). An absolute value of a threshold voltage in the third region 76 is thus higher than that in the fourth region 78, and occurrence of parasitic BTBT in the channel layer 75 placed on the source end E12 is suppressed. As a result, degradation of the SS characteristics is suppressed.

Further, the gate electrode 40 covers the part above the source end E12. Therefore, an electric field from the gate electrode 40 is applied to the source end E12, and thus a depletion layer is difficult to be extended at the source end E12, and the on-current Ion between the source layer 60 and the channel layer 75 can flow into the drain layer 50 without being blocked at the source end E12. As a result, the on-current Ion of the TFET 200 can be maintained.

As explained above, the TFET 200 according to the second embodiment uses the wide-Eg material Si for the third region 76 of the channel layer 75 and the narrow-Eg material SiGe for the fourth region 78. Further, the gate electrode 40 covers the part above the source end E12. Therefore, the P-TFET 200 can obtain steep SS characteristics and a large on-current Ion, and can break the trade-off relationship between the SS characteristics and the on-current Ion.

Next, a manufacturing method of the P-TFET 200 according to the second embodiment is explained.

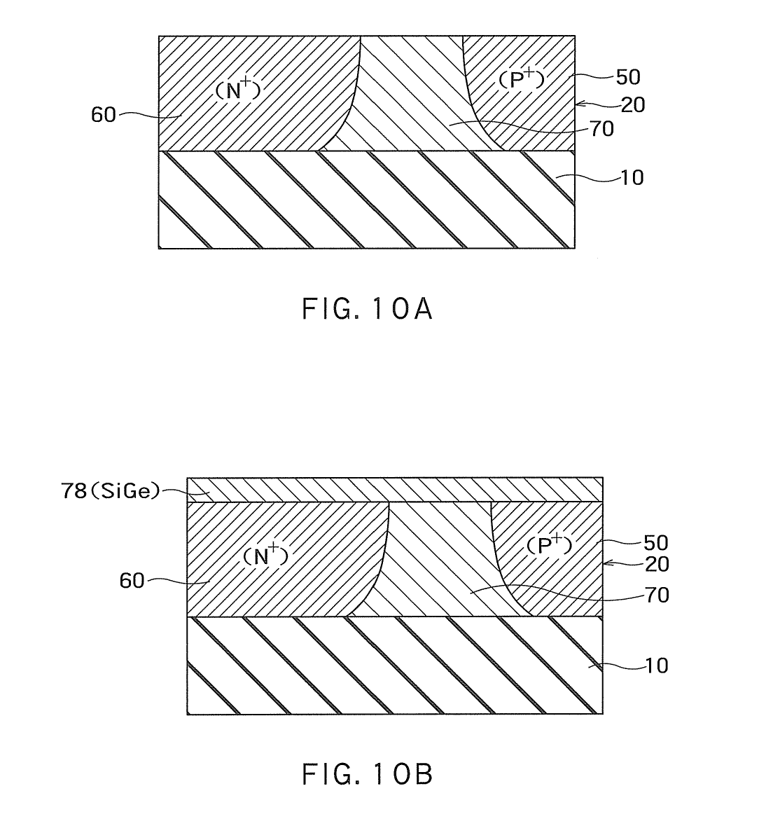

FIGS. 10A to 13 are cross-sectional views showing an example of the manufacturing method of the P-TFET 200 according to the second embodiment.

As explained with reference to FIGS. 5B and 6A, an impurity is implanted in a region where the source layer 60 is formed and a region where the drain layer 50 is formed by a lithography technique and ion implantation. In the second embodiment, an N-type impurity is implanted in the region where source layer 60 is formed and a P-type impurity is implanted in the region where the drain layer 50 is formed.

Next, activation annealing of an impurity is performed by RTA (Rapid Thermal Annealing) and the like. As a result, as shown in FIG. 10A, the drain layer 50 and the source layer 60 are formed. In the second embodiment, the narrow-Eg material SiGe is not formed in the region where the source layer 60 is formed. The entire source layer 60 is thus formed using the wide-Eg material Si that contains an N-type impurity.

Next, as shown in FIG. 10B, a narrow-Eg material (hereinafter, also “material for the fourth region 78”) is formed on the semiconductor layer 20 by epitaxial CVD. For example, the narrow-Eg material is at least one of SiGe, Ge, and InGaAs.

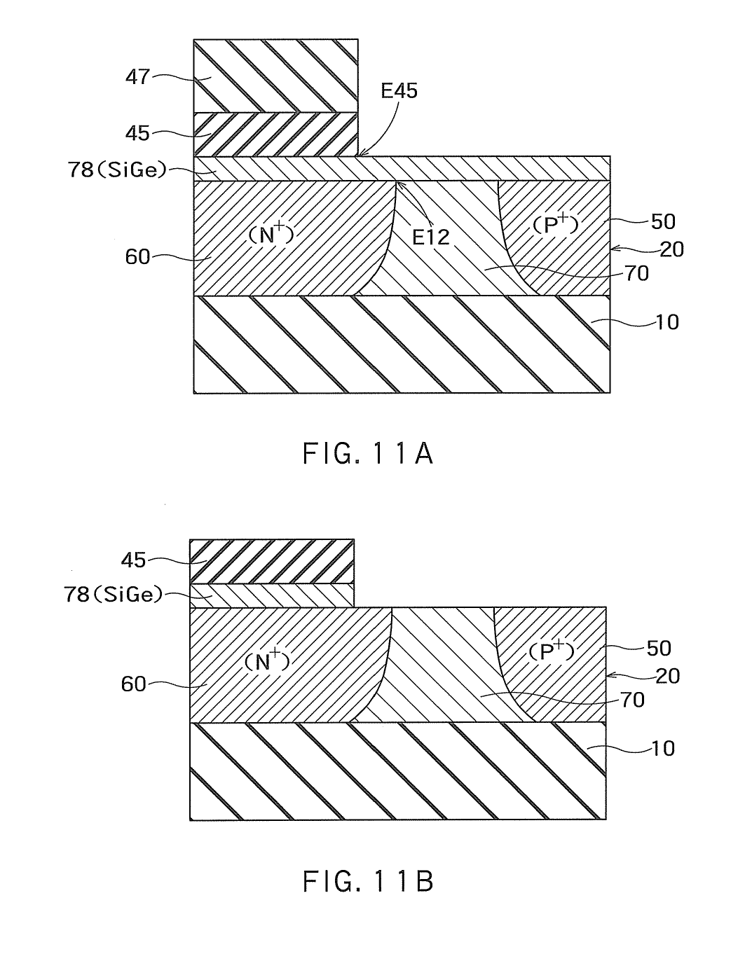

Next, a material for the hard mask 45 is deposited on the material for the fourth region 78 and is processed by a lithography technique and RIE. In FIG. 11A, reference numeral 47 denotes a photoresist. As shown in FIG. 11A, the hard mask 45 is thus formed on a region where the fourth region 78 is formed. For example, the hard mask 45 is formed of SiN. A drain side end E45 of the hard mask 45 is nearer to a side of the source layer 60 than the source end E12. That is, the source layer 60 is extended further to a side of the drain layer 50 than the hard mask 45.

After the photoresist 47 is removed, as shown in FIG. 11B, the narrow-Eg material other than the fourth region 78 is wet etched by using the hard mask 45 as a mask. For example, the narrow-Eg material other than the fourth region 78 is removed by using a mixed solution of ammonia water and hydrogen peroxide water (SC1) and the like.

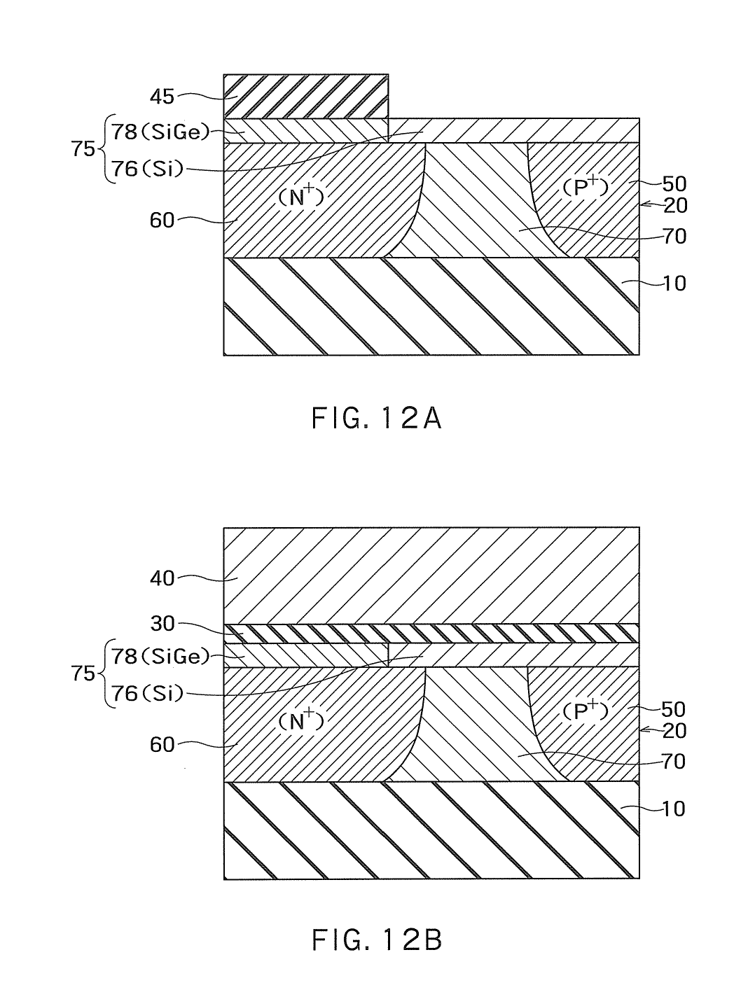

Next, as shown in FIG. 12A, a wide-Eg material is formed in the region other than the fourth region 78 by epitaxial CVD by using the hard mask 45 as a mask. The region other than the fourth region 78 includes the third region 76, and thus the wide-Eg material is also formed in the third region 76. For example, the wide-Eg material is Si.

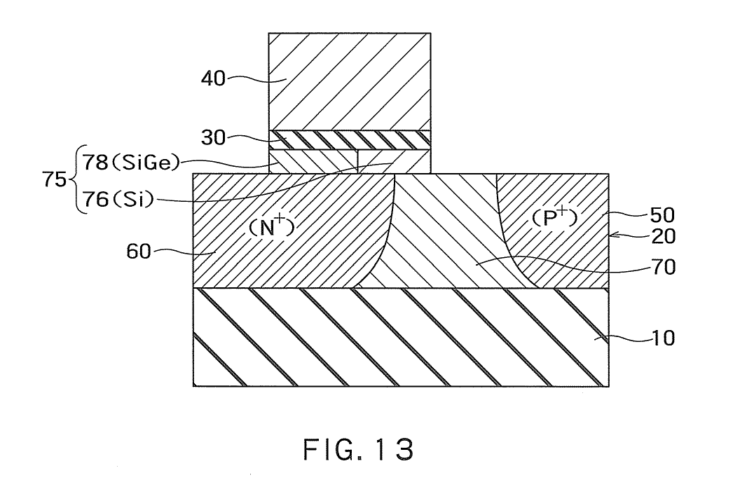

After the hard mask 45 is removed by wet etching using a hot phosphoric acid and the like, as shown in FIG. 12B, the gate dielectric film 30 and the gate electrode 40 are formed by a method similar to the method explained with reference to FIG. 7A. Next, the gate electrode 40, the gate dielectric film 30, and the channel layer 75 (the semiconductor layer 20) are processed by a lithography technique and RIE so that a bottom surface of the gate electrode 40 covers the part above the source end E12. As a result, a configuration shown in FIG. 13 is obtained.

Thereafter, the interlayer dielectric film 90, contacts (not shown), metal wires (not shown), and the like are formed, so that the P-TFET 200 shown in FIG. 8 is completed.

According to the second embodiment, the wide-Eg material Si is used for the third region 76 of the channel layer 75, and the narrow-Eg material SiGe is used for the fourth region 78 of the channel layer 75. Therefore, parasitic BTBT is prevented from occurring in the third region 76 of the channel layer 75 placed on the source end E12 and BTBT becomes easy to occur between the fourth region 78 of the channel layer 75 and the source layer 60. Degradation of the SS characteristics is thus suppressed, and a threshold voltage is reduced and the on-current Ion is increased. Further, the gate electrode 40 covers the part above the source end E12. Therefore, an electric field from the gate electrode 40 is applied to the source end E12, and thus the on-current Ion can flow between the drain layer 50 and the source layer 60 without being blocked by a depletion layer at the source end E12. As a result, the P-TFET 200 according to the second embodiment can break the trade-off relationship between the SS characteristics and the on-current Ion.

### THIRD EMBODIMENT

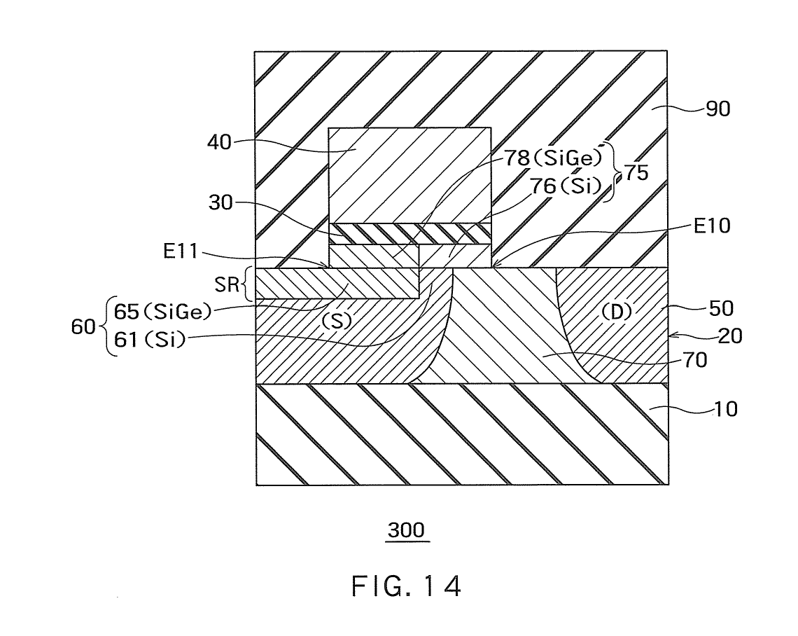

FIG. 14 is a cross-sectional view showing a configuration of a complementary TFET (hereinafter, also “C-TFET”) 300 according to a third embodiment. While FIG. 14 shows only one TFET 300, both an N-TFET and a P-TFET can be mounted on a substrate.

In the C-TFET 300, the source layer 60 includes the first region 61 and the second region 65, and the channel layer 75 includes the third region 76 and the fourth region 78. That is, the third embodiment is a combination of the first and second embodiments.

The first region 61 and the third region 76 are formed using a wide-Eg material serving as a first material (“third material”). The second region 65 and the fourth region 78 are formed using a narrow-Eg material serving as a second material (“fourth material”). As explained above, for example, the wide-Eg material is Si. For example, the narrow-Eg material is formed of at least one of SiGe, Ge, and InGaAs. In the third embodiment, SiGe is used as the narrow-Eg material.

The TFET 300 can be applied to both an N-TFET and a P-TFET. For example, to cause the TFET 300 to be an N-TFET, it suffices that the conductivity type of the source layer 60 is P⁺ and the conductivity type of the drain layer 50 is N⁺. To cause the TFET 300 to be a P-TFET, it suffices that the conductivity type of the source layer 60 is N⁺ and the conductivity type of the drain layer 50 is P⁺. Other configurations of the TFET 300 can be identical to corresponding ones of the TFET 100 or the TFET 200 according to the first or second embodiment, respectively.

When the TFET 300 is an N-TFET, operations of the TFET 300 are identical to those of the TFET 100 according to the first embodiment. On the other hand, when the TFET 300 is a P-TFET, the operations of the TFET 300 are identical to those of the TFET 200 according to the second embodiment.

In the TFET 300, the wide-Eg material Si is used for both the first region 61 of the source layer 60 and the third region 76 of the channel layer 75. Therefore, even when the TFET 300 is either an N-TFET or a P-TFET, occurrence of parasitic BTBT at the source end E12 can still be suppressed.

When the TFET 300 is an N-TFET, the narrow-Eg material SiGe is used for the second region 65 of the source layer 60.

BTBT thus becomes easy to occur between the second region 65 and the channel layer 75. At this time, the narrow-Eg material SiGe is also used for the fourth region 78 of the channel layer 75. However, as indicated by the alternate long and short dash line Cn in FIG. 2, an energy level of a valence band on a side of the channel layer 75 only comes close to that of a conduction band, and the energy level of the conduction band is not changed. Accordingly, the probability of occurrence of BTBT between the second region 65 and the channel layer 75 is identical to that in the first embodiment.

When the TFET 300 is a P-TFET, the narrow-Eg material SiGe is used for the fourth region 78 of the channel layer 75. BTBT thus becomes easy to occur between the source layer 60 and the fourth region 78. At this time, the narrow-Eg material SiGe is also used for the second region 65 of the source layer 60. However, as indicated by the alternate long and short dash line Cp in FIG. 9, an energy level of a valence band on a side of the source layer 60 only comes close to that of a conduction band, and the energy level of the conduction band is not changed. Accordingly, the probability of occurrence of BTBT between the source layer 60 and the fourth region 78 is identical to that in the second embodiment.

Further, the gate electrode 40 covers the part above the source end E12. Therefore, the on-current Ion can flow into the drain layer 50 without being blocked by a depletion layer at the source end E12.

Accordingly, when the C-TFET 300 is an N-TFET, effects identical to those of the first embodiment can be achieved, and when the C-TFET 300 is a P-TFET, effects identical to those of the second embodiment can be achieved.

As explained above, by simply interchanging the conductivity type of an impurity between the source layer 60 and the drain layer 50, the third embodiment can be applied to both an N-TFET and a P-TFET. Therefore, if the TFET 300 according to the third embodiment is used, both an N-TFET and a P-TFET can be easily mounted on the same substrate. That is, a C-TFET with steep SS characteristics and a large on-current Ion can be easily manufactured.

Next, a manufacturing method of the C-TFET 300 according to the third embodiment is explained.

The steps shown in FIGS. 3 to 5A according to the first embodiment are performed first.

Next, at the step explained with reference FIG. 5B, an impurity is implanted in a region where the source layer 60 is formed by a lithography technique and ion implantation. By performing a lithography technique and ion implantation repeatedly, a P-type impurity is implanted in a region where the source layer 60 is formed in an N-TFET, and an N-type impurity is implanted in a region where the source layer 60 is formed in a P-TFET.

Next, at the step explained with reference to FIG. 6A, an impurity is implanted in a region where the drain layer 50 is formed by a lithography technique and ion implantation. By performing a lithography technique and ion implantation repeatedly, an N-type impurity is implanted in a region where the drain layer 50 is formed in an N-TFET, and a P-type impurity is implanted in a region where the drain layer 50 is formed in a P-TFET.

Next, the steps shown in FIGS. 10B to 13 according to the second embodiment are performed. As a result, the TFET 300 shown in FIG. 14 is completed.

As explained above, by simply interchanging the conductivity type of an impurity between the source layer 60 and the drain layer 50, the third embodiment can be applied to both an N-TFET and a P-TFET. Therefore, according to the third embodiment, both the N-TFET and the P-TFET can be easily mounted on the same substrate.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a gate dielectric film on the semiconductor layer;
a gate electrode above the semiconductor layer via the gate dielectric film;
a first conductivity type drain layer in the semiconductor layer on one end side of the gate electrode;
a second conductivity type source layer in the semiconductor layer on the other end side of the gate electrode and below the gate electrode; and
a channel layer between the gate dielectric film and the source layer, wherein
a drain side end of the source layer is below a bottom surface of the gate electrode,
a region of the drain side end of a surface region of the source layer is formed using a first material, and a region of the surface region of the source layer other than the drain side end is formed using a second material, and
an energy band gap of the first material is larger than that of the second material.

2. The device of claim 1, wherein a tunneling probability of a junction constituted only by the first material is lower than that of a junction constituted by the first material and the second material.

3. The device of claim 1, wherein the first material is formed of Si.

4. The device of claim 1, wherein the second material is formed of at least one of SiGe, Ge, and InGaAs.

5. The device of claim 1, wherein the first conductivity type is an N-type and the second conductivity type is a P-type.

6. The device of claim 1, wherein an impurity concentration of the channel layer is lower than that of the source layer or the drain layer.

7. A semiconductor device comprising:
a semiconductor layer;
a gate dielectric film on the semiconductor layer;
a gate electrode above the semiconductor layer via the gate dielectric film;
a first conductivity type drain layer in the semiconductor layer on one end side of the gate electrode;
a second conductivity type source layer in the semiconductor layer on the other end side of the gate electrode and below the gate electrode; and
a channel layer between the gate dielectric film and the source layer, wherein
a drain side end of the source layer is below a bottom surface of the gate electrode,
a part of the channel layer placed on the drain side end of the source layer is formed using a first material, and a part of the channel layer placed on a region other than the drain side end of the source layer is formed using a second material, and
an energy band gap of the first material is larger than that of the second material.

8. The device of claim 7, wherein a tunneling probability of a junction constituted only by the first material is lower than that of a junction constituted by the first material and the second material.

9. The device of claim 7, wherein the first material is formed of Si.

10. The device of claim 7, wherein the second material is formed of at least one of SiGe, Ge, and InGaAs.

11. The device of claim 7, wherein the first conductivity type is a P-type and the second conductivity type is an N-type.

12. The device of claim 7, wherein an impurity concentration of the channel layer is lower than that of the source layer or the drain layer.

13. A semiconductor device comprising:
a semiconductor layer;
a gate dielectric film on the semiconductor layer;
a gate electrode above the semiconductor layer via the gate dielectric film;
a first conductivity type drain layer in the semiconductor layer on one end side of the gate electrode;
a second conductivity type source layer in the semiconductor layer on the other end side of the gate electrode and below the gate electrode; and
a channel layer between the gate dielectric film and the source layer, wherein
a drain side end of the source layer is below a bottom surface of the gate electrode,
a region of the drain side end of a surface region of the source layer is formed using a first material and a region of the surface region of the source layer other than the drain side end is formed using a second material,
a part of the channel layer placed on the drain side end of the source layer is formed using a third material and a part of the channel layer placed on a region other than the drain side end of the source layer is formed using a fourth material,
an energy band gap of the first material is larger than that of the second material, and
an energy band gap of the third material is larger than that of the fourth material.

14. The device of claim 13, wherein a tunneling probability of a junction constituted only by the first material is lower than that of a junction constituted by the first material and the second material.

15. The device of claim 13, wherein the first material is formed of Si.

16. The device of claim 13, wherein the second material is formed of at least one of SiGe, Ge, and InGaAs.

17. The device of claim 13, wherein the third material is formed of Si.

18. The device of claim 13, wherein the fourth material is formed of at least one of SiGe, Ge, and InGaAs.

19. The device of claim 13, wherein the first conductivity type is an N-type and the second conductivity type is a P-type, or the first conductivity type is a P-type and the second conductivity type is an N-type.

20. The device of claim 13, wherein an impurity concentration of the channel layer is lower than that of the source layer or the drain layer.
